(19) United States
(12) Patent Application Publication
(10) Pub. No.: US 2009/0121264 A1
(43) Pub. Date: May 14, 2009

(54) CMOS IMAGE SENSOR AND METHOD OF FORMING THE SAME

(76) Inventor: Ching-Hung Kao, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/938,757

(22) Filed: Nov. 12, 2007

(51) Int. Cl. H01L 31/112; H01L 21/50

(52) U.S. Cl. 257/291; 438/59; 257/E31.114; 257/E21.04

(57) ABSTRACT

A CMOS image sensor is formed utilizing a through-poly implantation process. First, a substrate including a photo-sensing region and a transistor region is provided. Subsequently, at least a gate structure is formed on a surface of the substrate within the transistor region. Thereafter, an ion implantation process is performed on the substrate to form a first conductive type well in the substrate through the gate structure. Since the ion implantation process implants ions into the substrate to a channel region of the transistor through the gate structure, the implant depth of the uncovered parts of the substrate is deeper than the implant depth of the parts of the substrate covered by the gate structure, and defects caused by the energy of the ion implantation process are prevented within the channel region.

### BACKGROUND OF THE INVENTION

1. Field of the Invention

The present invention relates generally to image sensors and more particularly, to a complementary metal-oxide-semiconductor (CMOS) image sensor that can reduce a dark current value.

2. Description of the Prior Art

CMOS image sensors (CIS) are commonly used in a various image sensing devices at present. Photodiodes of the CMOS image sensor can sense an optical signal and therefore generate electric charges; and transistors of the CMOS image sensor can transfer the generated electric charges into a digital signal. The CMOS image sensor also has advantages of high quantum efficiency and low read-out noise, making its usage popular with electronic products, such as camera phones and digital cameras.

A traditional CMOS image sensor includes a photodiode, such as a PN diode having an N-type region and a P-type well. A transfer gate is provided at side of the photodiode for transferring electric charges generated in the photodiode to a floating node. Typically, the floating node is coupled to a gate of a source follower transistor. The source follower transistor provides an output signal to a row select access transistor having a gate. A reset transistor having a gate resets the floating node to a specified charge level before each charge transfer from the photodiode.

Please refer to FIG. 1 that illustrates a schematic diagram of a traditional CMOS image sensor. The traditional CMOS image sensor 30 includes a semiconductor substrate 10 and a plurality of shallow trench isolation (STI) structures 14 formed in the semiconductor substrate 10. A plurality of pixel units 12 can be defined by the STI structures 14. Each pixel unit 12 includes a plurality of transistor structures (not shown in the drawing). A photodiode 20 is applied to the CMOS image sensor 30 as a source of a transistor in the pixel unit 12, so that the electric charges generated in the photodiode 20 can be transferred to a floating node (not shown in the drawing). Each photodiode 20 has an N-type region 16 and a P-type well 18 forming a device for sensing light intensity. Furthermore, a series of dielectric layers and multilevel interconnects are employed. For instance, the semiconductor substrate 10 is covered by an interlevel dielectric (ILD) layer 26 and two intermetal dielectric (IMD) layers 22 and 24, and metal lines 23 and 25 are formed in the IMD layers 22 and 24.

The CMOS image sensor deals with signal data according to the current generated from the transistor structures. For example, light current serves as signal data, which are generated when the photodiode is illuminated, and dark current serves as noise, which is generated when the photodiode is not illuminated. Therefore, the CMOS image sensor can sense the magnitude of the lightness according to the ratio of the signal to noise. Excessive dark current seriously affects the sensitivity of the CMOS image sensor because there is insufficient ability to distinguish between the light currents and the dark currents. Therefore, minimizing the dark current generated in the CMOS image sensor is still a great challenge for CMOS image sensor fabrication.

### SUMMARY OF THE INVENTION

Therefore the present invention provides a CMOS image sensor and a manufacturing method thereof to reduce the dark current so that the sensitivity of the CMOS image sensor is increased.

From one aspect of the present invention, a method of forming a CMOS image sensor is disclosed. First, a substrate is provided. The substrate includes at least a photo-sensing region and at least a transistor region. Subsequently, at least a gate structure is formed on a surface of the substrate within the transistor region. Next, an ion implantation process is performed on the substrate through the gate structure to form a first conductive type well within the substrate in the transistor region. The first conductive type well includes at least a first well region and at least a second well region.

From one aspect of the present invention, a CMOS image sensor is disclosed. The CMOS image sensor includes a substrate, at least a photodiode disposed in the substrate, at least a gate structure disposed on the substrate by a side of the photodiode, at least a second conductive type region disposed within the substrate at a side of the gate structure opposite to the photodiode, and at least a first conductive type well disposed within the substrate. The first conductive type well includes at least a first well region and at least a second well region. The first well region is disposed under the gate structure, and the second well region is disposed under the second conductive type region. An implant depth of the second well region is deeper than an implant depth of the first well region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 illustrates a schematic diagram of a traditional CMOS image sensor;

FIG. 2 to FIG. 5 are schematic diagrams illustrating a method for forming a CMOS image sensor in accordance with the first embodiment of the present invention;

FIG. 6 and FIG. 7 are schematic diagrams illustrating methods for forming a CMOS image sensor in accordance with the second and the third preferred embodiments of the present invention respectively;

FIG. 8 to FIG. 10 are schematic diagrams illustrating methods for forming a CMOS image sensor in accordance with the fourth to the sixth preferred embodiments of the present invention respectively;

FIG. 11 to FIG. 15 are schematic diagrams illustrating a method for forming a CMOS image sensor in accordance with the seventh preferred embodiment of the present invention;

FIG. 16 and FIG. 17 are schematic diagrams illustrating methods for forming a CMOS image sensor in accordance with the eighth and the ninth preferred embodiments of the present invention respectively; and

FIG. 18 to FIG. 20 are schematic diagrams illustrating methods for forming a CMOS image sensor in accordance with the tenth to the twelfth preferred embodiments of the present invention respectively.

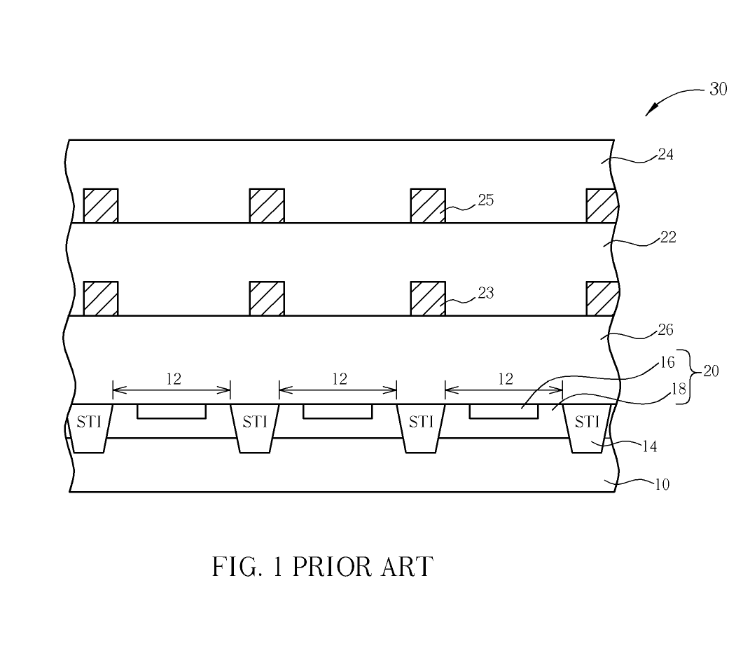

### DETAILED DESCRIPTION

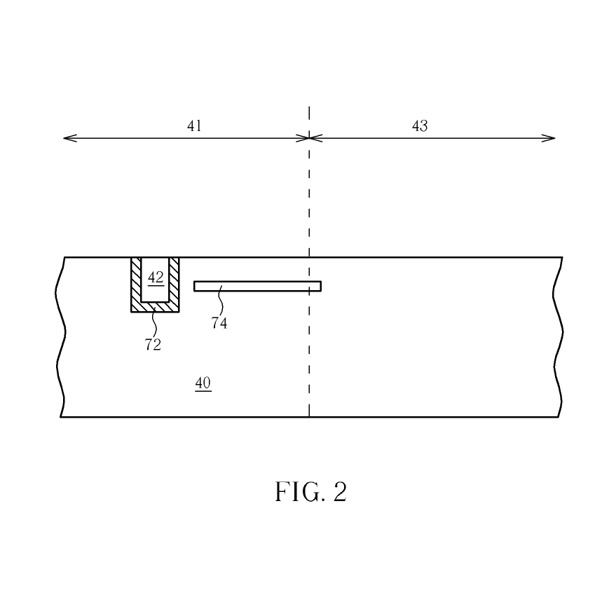

Please refer to FIG. 2 to FIG. 5. FIG. 2 to FIG. 5 are schematic diagrams illustrating a method for forming a CMOS image sensor in accordance with the first preferred embodiment of the present invention. As FIG. 2 diagrammatically shows, a substrate 40, which can include a p-type epitaxial layer (P-epi layer), a silicon substrate or a silicon-on-insulator (SOI) substrate, is first provided. At least a photo-sensing region 41 and at least a transistor region 43 are defined on the substrate 40, and the photo-sensing region 41 are disposed at the left of the transistor region 43. The substrate 40 can further include at least an STI structure 42, at least a P-field 72 and at least a N-type region 74. These fabricating processes are well-known for those skilled in the art. For example, at least a trench (not shown in the drawings) is first formed in the substrate 40 and an insulator (not shown in the drawings) is thereafter formed to cover the substrate 40 and to fill up the trench. Following that, a CMP process is performed to form a STI structure 42 in the substrate 40. The P-field 72 and the N-type region 74 are formed by implanting P-type dopants and N-type dopants into the substrate 40 respectively. The STI structure 42 isolates the pixel units of the CMOS image sensor one from another. The STI structure can be replaced by other insulated structures such as field oxide (FOX).

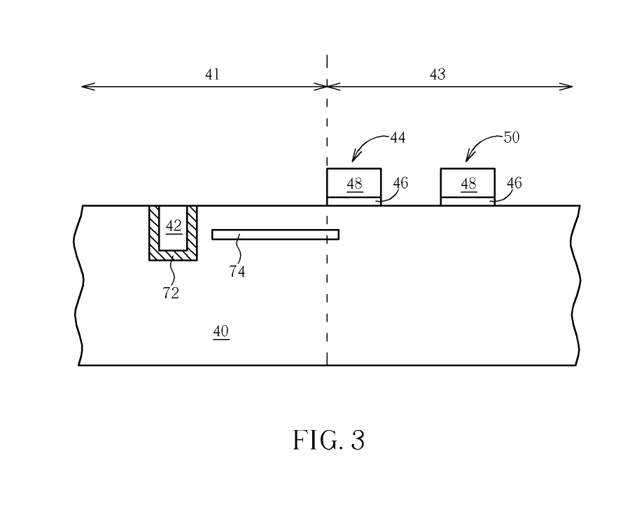

As shown in FIG. 3, a dielectric layer (not shown) can be substantially formed. The dielectric layer can be a silicon nitride layer forming by thermal oxidation, or any dielectric material forming by deposition. Then, a conductive layer (not shown) can be formed on the dielectric layer. The conductive layer can include polysilicon, polycide, metal or metal alloys, among others. Following that, a lithographic and etching process can be performed to etch the dielectric layer and the conductive layer to form gates of transistors on the substrate 40. For example, a transfer gate 44 and a reset gate 50 can be formed as shown in FIG. 3. Both the transfer gate 44 and the reset gate 50 can include a gate dielectric 46 and a conductor 48 disposed on the gate dielectric 46.

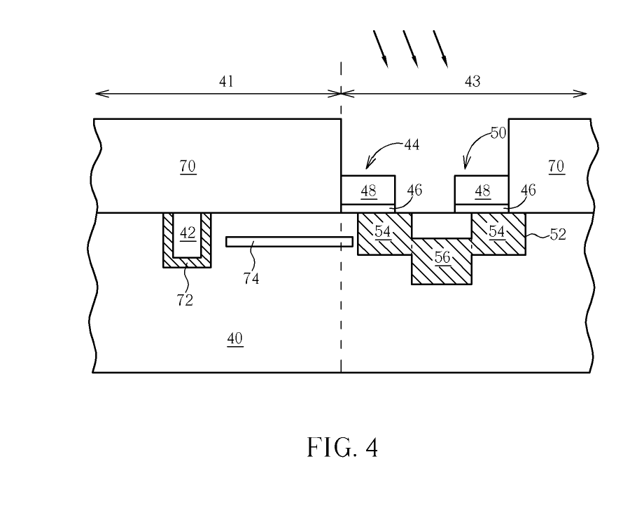

Next, as shown in FIG. 4, an ion implant mask 70 is formed on the substrate 40, and thereafter an ion implantation process is performed on the substrate 40. The ion implantation process can penetrate through the transfer gate 44 and the reset gate 50, and forms a P-type well 52 within the substrate 40 in the transistor region 43. The ion implant mask 70 covering the photo-sensing region 41 can resist the ion implantation process, so that the underlying substrate 40 can be isolated from the ion implantation. The materials of the ion implant mask 70 can include negative or positive photoresists in general, and the thickness of the ion implant mask 70 can be adjusted according to the intensity of the ion implantation process. Referring to the semiconductor processes in general, the implant energy of this ion implantation process is approximately greater than or equal to 90 kiloelectronvolt (KeV), so that the dopants can penetrate through the transfer gate 44 and the reset gate 50 into the substrate 40 for forming the P-type well 52. The greater the intensity of the ion implantation process is, the thicker the thickness of the ion implant mask 70 should be for isolating the ion implantation process. The ion implant mask 70 does not have to resist the ion implantation all on its own. Basically speaking, the ion implant mask 70 is applied for preventing the ion implantation process from penetrating through the laminated construction of the ion implant mask 70, the conductor 48 and the gate dielectric 46, and allows the ion implantation process to penetrate through the laminated construction of the conductor 48 and the gate dielectric 46 simultaneously.

The implant depth at parts of the substrate 40 not shadowed by the transfer gate 44 nor by the reset gate 50 is deeper than the implant depth at parts of the substrate 40 shadowed by the transfer gate 44 or by the reset gate 50. Accordingly, the P-type well 52 can include two first well regions 54 and a second well region 56. The first well regions 54 are disposed under the transfer gate 44 and the reset gate 50; and the second well region 56 is disposed within the substrate 40 between the transfer gate 44 and the reset gate 50. The implant depth of the second well region 56 is deeper than the implant depth of the first well regions 54. It is noteworthy that, the ion implantation process is performed toward the substrate 40 and tilts from the photo-sensing region 41 toward the transistor region 43 in this embodiment, and there is an included angle between the implant direction of the ion implantation process forming the P-type well 52 and the normal of the surface of the substrate 40. Thus, the transfer gate 44 and the reset gate 50 overlap the first well regions 54, and the first well regions 54 are not exactly disposed under the transfer gate 44 and the reset gate 50. The position of one first well region 54 is farther than the position of the transfer gate 44 from the photo-sensing region 41, while the position of another first well region 54 is farther than the position of the reset gate 50.

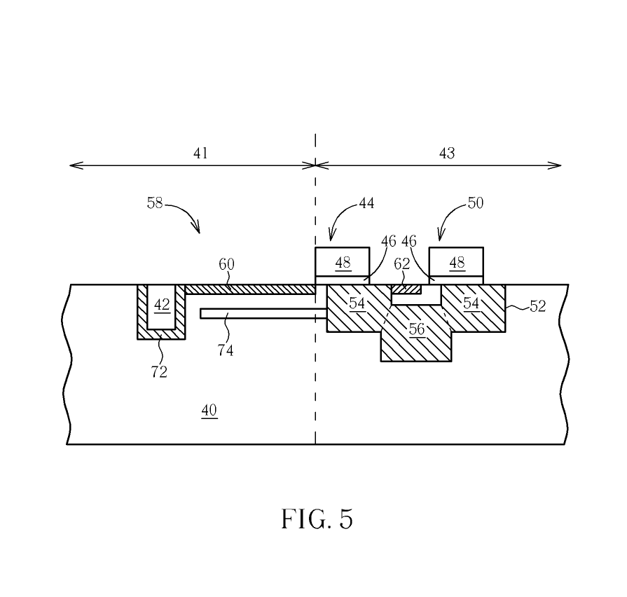

As shown in FIG. 5, the ion implant mask 70 is next removed, and an activating process is performed on the substrate 40. Furthermore, a photodiode 58 is completed in the photo-sensing region 41, and at least a N-type region 62 is formed within the substrate 40 in the transistor region 43 by utilizing a plurality of patterning processes and a plurality of ion implantation processes. For instance, P-type dopants are first implanted into the substrate 40 in the photo-sensing region 41 to form a surface P+ pinning layer 60, and thereafter N-type dopants, such as phosphorous or arsenic, are implanted into the substrate 40 in the transistor region 43 to form a N-type region 62 functioning as a floating node, by the high-energy implantation process.

As known to those skilled in the art, the concentration profile of dopants in the P-type well 52 may change after the activating process. Although the doped regions and the doped wells are delineated by lines in the drawings in the present invention for the major locations of these dopants, there need not be any discrete visible boundaries between regions in the actual body. Also, it is appreciated that a small amount of dopants may still be included outside these doped regions. In addition, the actual shapes of the doped regions and the actual shapes of the doped wells can be changed according to different process parameters or according to different arrangements of components. Next, a series of dielectric layers, multilevel interconnects and optical lenses (not shown in the drawings) can be formed on the substrate 40 according to the product design in the present invention, and a CMOS image sensor is therefore formed. In addition, as known to those skilled in the art, the N-type dopants can exchange with the P-type dopants for the doped regions or the doped wells in the present invention. The conductive type of the dopants should not be limited to the embodiment.

Since the ion implantation process of the present invention can penetrate through the gate conductor 48, and implant the dopants into the channel region of the transistor, the present invention can have the following advantages. First, a high-energy implantation process is directly performed on the exposed surface of the substrate in the conventional process. Therefore, the lattice structure in the channel region is inevitably damaged, leading to an increase of dark current and a serious decrease of the sensitivity of the photodiode. On the contrary, the implant depth and position of the P-type well 52 can be easily adjusted by the gate conductor 48, which is formed in advance. The gate structures can be a buffer to protect the channel region from the high-energy of the ion implantation process without additional processes. Thus, the fabricating process disclosed in the present invention can prevent the defects caused by the ion implant energy in the channel regions of the transistors, and there is no damage to the gate structures of the transistors.

Secondly, the prior art N-type region (floating node) is directly surrounded by the P-type well, so the dark current easily occurs from the defects of the CMOS image sensor, and flows into the floating node. On the contrary, the ion implantation process of the present invention can be a self-aligned process utilizing the gate structure, so that the implant depth of the second well region 56 having the P-type conductivity under the N-type region 62 is deeper in the first the embodiment. Thus, the current occurring in the photodiode 58 can mainly flow through the channel region under the transfer gate 44 and flows into the N-type region 62. Accordingly, a dark current does not easily occur in the N-type region 62 in the CMOS image sensor, and a floating node leakage can also be avoided between the P-type region 62 and the N-type well 52. Furthermore, the tilted ion implantation process can prevent an end of the N-type region 74 from extending into the first well region 54 of the channel region. Accordingly, the light current can flow into the N-type region 62 as well, while it is more difficult for the existence of a dark current. In light of this, the CMOS image sensor can have a better layout in the present invention, and the dark current intensity therefore is reduced.

In addition, when a P-epi layer is included in the substrate 40, the N-type region74 of the photo-sensing region 41 can directly contact the P-epi layer at bottom of the N-type region74 in the first embodiment. As a result, the junction depletion width of the photodiode 58 can be broadened, and the sensitivity of the photodiode 58 can therefore be improved.

It is proved by the experiment data that, in comparison with the prior art ion implantation process that is directly performed on the exposed substrate, the CMOS image sensor of the present invention can reduce the dark current intensity for about 80 percent (80%). For example, the dark current intensity of the CMOS image sensor in the first preferred embodiment is less than 5×10⁻¹² amperes, and the ability of the CMOS image sensor for detecting the optical signal is therefore effectively increased.

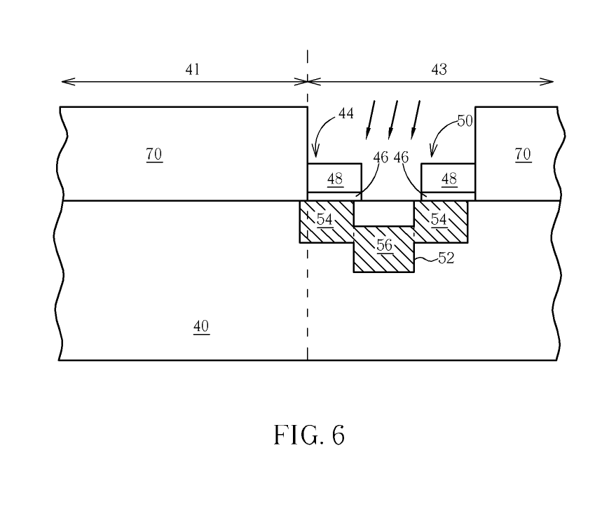

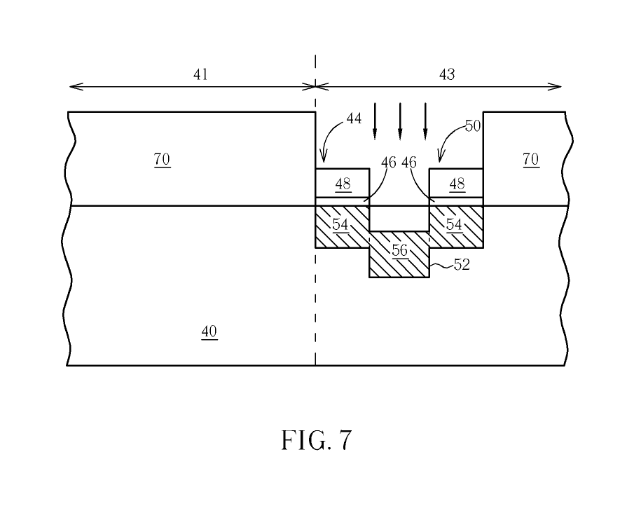

In above embodiment, there is an included angle between the implant direction of the ion implantation process forming the P-type well 52 and the normal of the surface of the substrate 40, and the titled ion implantation process is performed from the upper left corner to the lower right corner. In other embodiments of the present invention, the ion implantation process for forming the P-type well 52 can be performed from the upper right corner to the lower left corner, or substantially parallel to the normal of the surface of the substrate 40. Please make reference to FIG. 6 and FIG. 7, which are schematic diagrams illustrating methods for forming a CMOS image sensor in accordance with the second and the third preferred embodiments of the present invention respectively. As shown in FIG. 6, the ion implantation process is performed toward the substrate 40 and tilts from the transistor region 43 toward the photo-sensing region 41 in this embodiment for forming the P-type well 52. Thus, the position of one first well region 54 is nearer than the position of the transfer gate 44 from the photo-sensing region 41, while the position of another first well regions 54 is nearer than the position of the reset gate 50. As shown in FIG. 7, the ion implantation process for forming the P-type well 52 can be substantially parallel to the normal of the surface of the substrate 40, and the first well regions 54 can correspond to the transfer gate 44 and the reset gate 50. As mentioned above, since the ion implantation process of the present invention can penetrate through the gate conductor 48, and implant the dopants into the channel region of the transistor, the gate conductor 48 can prevent the defects caused by the ion implant energy in the channel region of the transistor, and the dark current intensity is therefore reduced. It is noteworthy that FIG. 6 and FIG. 7 do not show all the components in the photo-sensing region 41 for clarity of illustration. In practice, the STI structure 42 or various doped regions of the photo-sensing region 41 can be formed before, after or together with the various gate structures or doped regions of the transistor region 43.

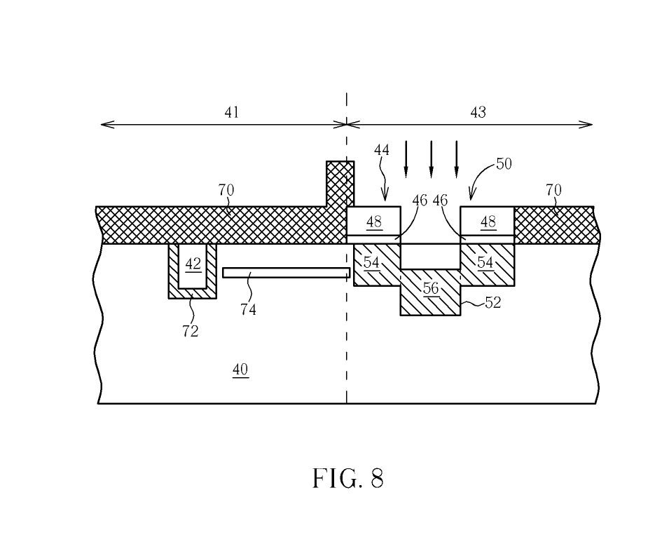

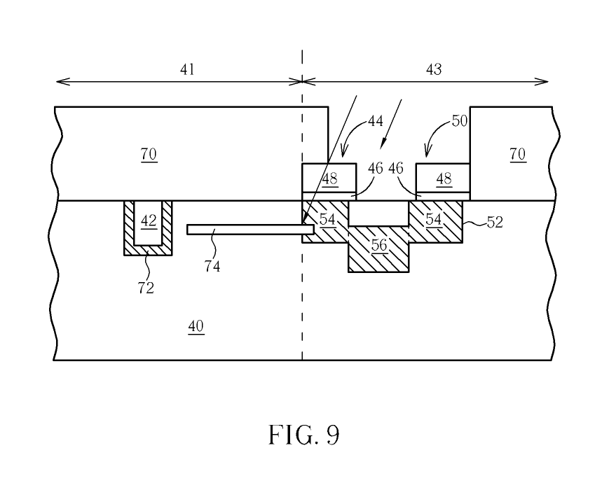

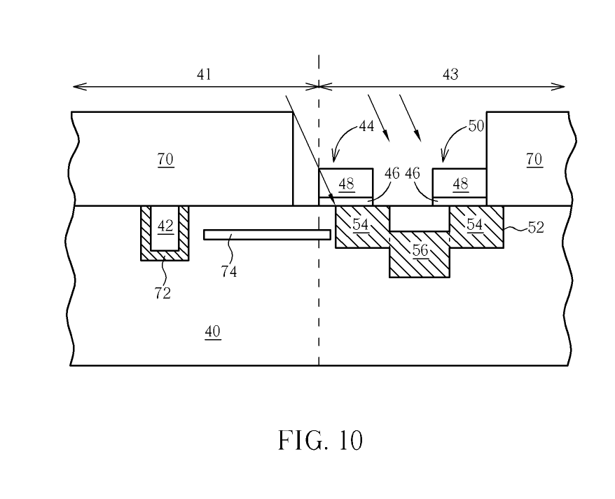

In addition, the direction of the ion implantation process and the exact position of the ion implant mask 70 in the present invention should not be limited to the above embodiments, and can be adjusted according to the process requirement or the product design. Please refer to FIG. 8 to FIG. 10, which are schematic diagrams illustrating methods for forming a CMOS image sensor in accordance with the fourth to the sixth preferred embodiments of the present invention respectively. As shown in FIG. 8 and FIG. 9, the ion implant mask 70 can cover parts of the transfer gate 44. As shown in FIG. 10, the ion implant mask 70 can have no contact with the transfer gate 44 if the angle of the tilted ion implantation is properly adjusted.

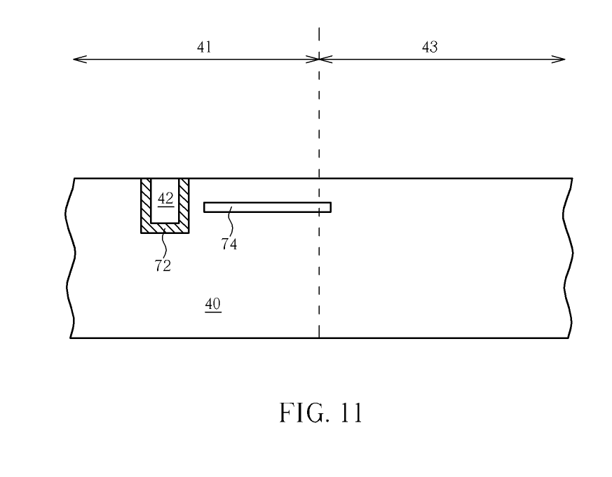

On the other hand, the P-type well 52 can be formed before the gate structures, such as the reset gate 44 and the transfer gate 50 in the present invention. Please refer to FIG. 11 to FIG. 15, which are schematic diagrams illustrating a method for forming a CMOS image sensor in accordance with the seventh preferred embodiment of the present invention. As FIG. 11 diagrammatically shows, a substrate 40 is first provided. At least a photo-sensing region 41 and at least a transistor region 43 are defined on the substrate 40, and the photo-sensing region 41 are disposed at the left of the transistor region 43. The substrate 40 can further include at least an STI structure 42, at least a P-field 72 and at least a N-type region 74.

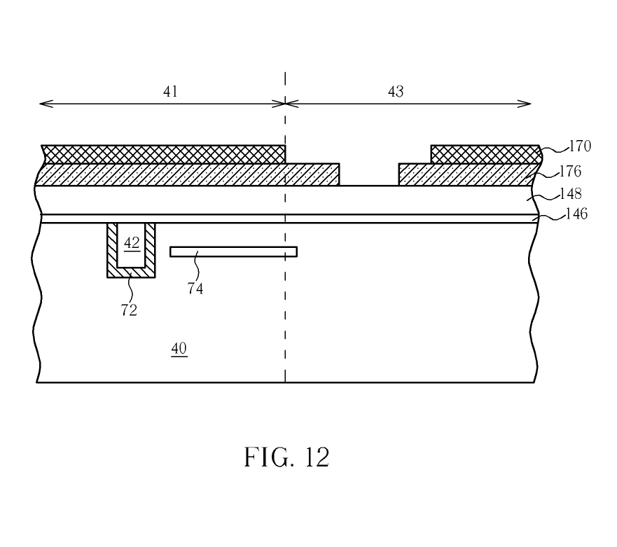

Next, as shown in FIG. 12, a dielectric layer 146 is formed on the surface of the substrate 40, a conductor 148 is formed on the dielectric layer 146, a patterned photoresist 176 is formed on the conductor 148, and thereafter an ion implant mask 170 is formed on the patterned photoresist 176. The patterned photoresist 176 can expose parts of the conductor 148 disposed between the predetermined position of the transfer gate and the predetermined position of the reset gate. The ion implant mask 170 not only exposes parts of the conductor 148 disposed between the predetermined position of the transfer gate and the predetermined position of the reset gate, but also expose parts of the patterned photoresist 176 disposed on the predetermined positions of these gate structures. The dielectric layer 146 can be a silicon nitride layer forming by thermal oxidation, or any dielectric material forming by deposition. The conductive layer can include polysilicon, polycide, metal or metal alloys, among others. The materials of the ion implant mask 170 or the patterned photoresist 176 can include negative or positive photoresists in general, and the thickness of the ion implant mask 170 or the patterned photoresist 176 can be adjusted according to the intensity of the ion implantation process. In addition, a half-tone photo mask can be applied for forming a photoresist mask having a step-shaped structure.

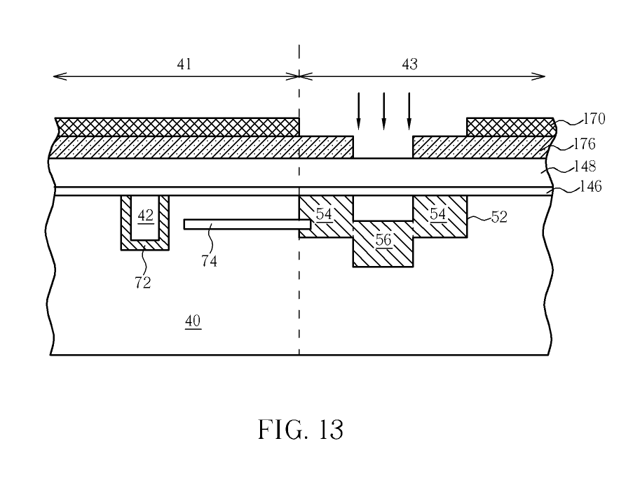

Afterward, as shown in FIG. 13, an ion implantation process is performed on the substrate 40. The ion implantation process can penetrate through the patterned photoresist 176, the conductor 148 and the dielectric layer 146, and forms a P-type well 52 within the substrate 40 in the transistor region 43. The ion implant mask 170 can resist the ion implantation process, so that the substrate 40 disposed under the ion implant mask 170 can be isolated from the ion implantation. The implant energy of this ion implantation process can be greater than 90 kiloelectronvolt (KeV), so that the dopants can penetrate through the laminated construction of the patterned photoresist 176, the conductor 148 and the dielectric layer 146, and do not penetrate through the laminated construction of the ion implant mask 170, the patterned photoresist 176, the conductor 148 and the dielectric layer 146.

The implant depth at parts of the substrate 40 not shadowed by the patterned photoresist 176 is deeper than the implant depth at parts of the substrate 40 shadowed by the patterned photoresist 176. Accordingly, the P-type well 52 can include two first well regions 54 and a second well region 56. The first well regions 54 are disposed under the patterned photoresist 176 not shadowed by the ion implant mask 170; and the second well region 56 is disposed under the conductor 148 not shadowed by the patterned photoresist 176. The implant depth of the second well region 56 is deeper than the implant depth of the first well regions 54. It is noteworthy that, the ion implantation process can be substantially parallel to the normal of the surface of the substrate 40 in this embodiment. In other embodiments, there can be an included angle between the implant direction of the ion implantation process forming the P-type well 52 and the normal of the surface of the substrate 40.

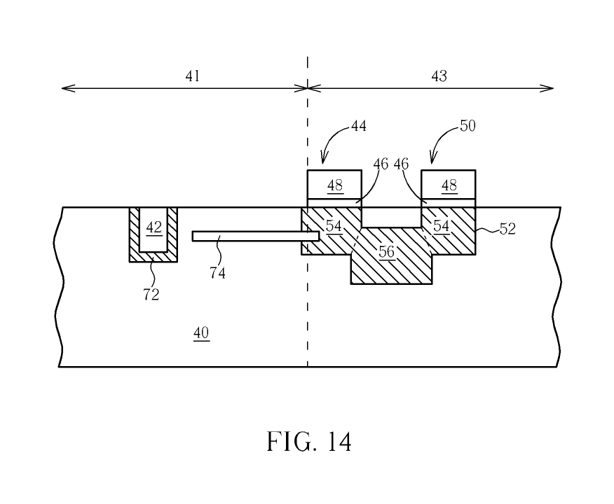

As shown in FIG. 14, the ion implant mask 170 and the patterned photoresist 176 are removed, and an activating process is next performed on the substrate 40. Thereafter, another patterned photoresist (not shown in the drawings) is formed on the conductor 148, and another lithographic and etching process can be performed on the conductor 148 and the dielectric layer 146 to form the designed gates of transistors on the substrate 40. For instance, the transfer gate 44 and the reset gate 50 can be formed as shown in FIG. 14. The positions and the sizes of the transfer gate 44 and the reset gate 50 are not affected by the P-type well 52 in this embodiment, and they can be adjusted according to the product design.

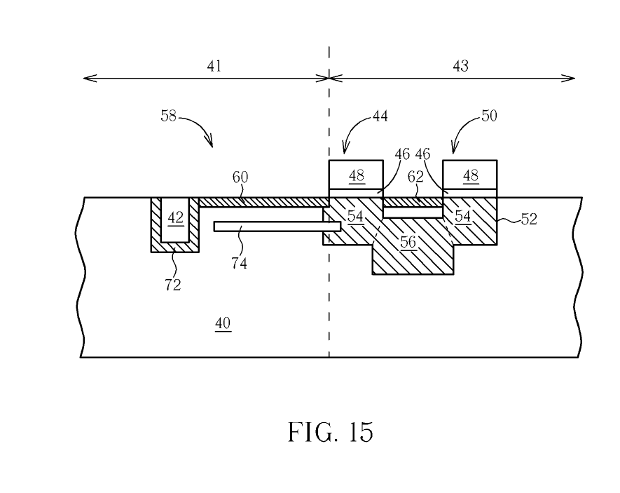

Furthermore, as shown in FIG. 15, a photodiode 58 is completed in the photo-sensing region 41, and the designed N-type region 62 is formed within the substrate 40 in the transistor region 43 by utilizing a plurality of patterning processes and a plurality of ion implantation processes. For example, P-type dopants are first implanted into the substrate 40 in the photo-sensing region 41 to form a surface P+ pinning layer 60, and thereafter N-type dopants, such as phosphorous or arsenic, are implanted into the substrate 40 in the transistor region 43 to form a N-type region 62 functioning as a floating node, by the high-energy implantation process. Next, a series of dielectric layers, multilevel interconnects and optical lenses (not shown in the drawings) can be formed on the substrate 40 according to the product design in the present invention, and a CMOS image sensor is therefore formed.

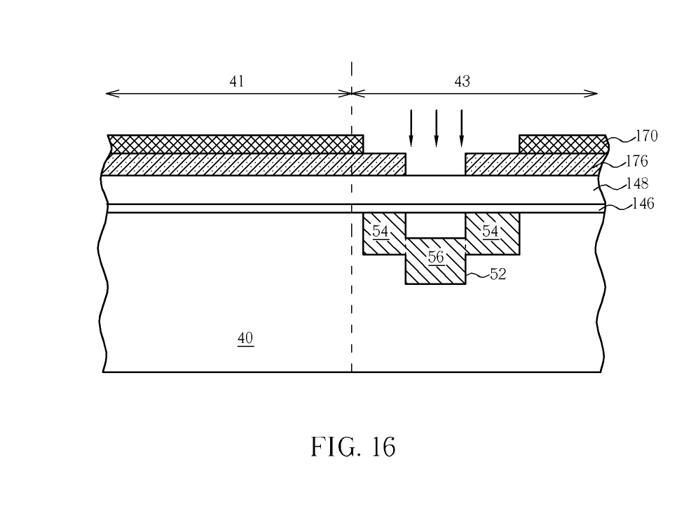

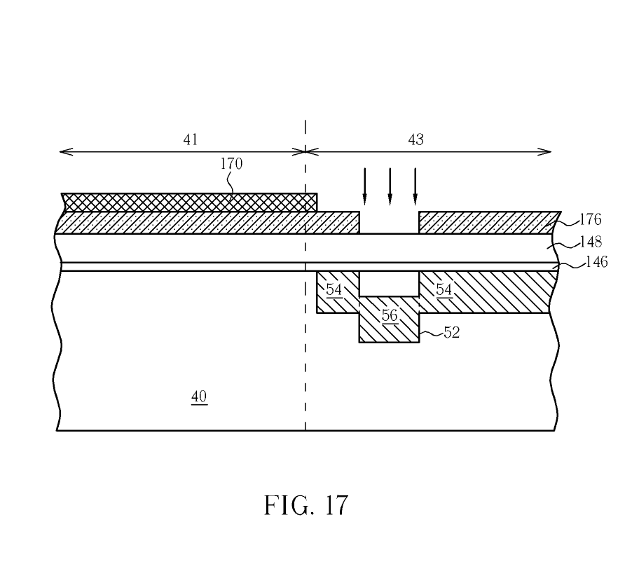

As mentioned above, the direction of the ion implantation process and the exact position of the ion implant mask 170 can be adjusted according to the process requirement or the product design. Please refer to FIG. 16 and FIG. 17, which are schematic diagrams illustrating methods for forming a CMOS image sensor in accordance with the eighth and the ninth preferred embodiments of the present invention respectively. As shown in FIG. 16, the ion implant mask 170 can cover parts of the transfer gate 44. As shown in FIG. 17, the ion implant mask 170 can also expose parts of the patterned photoresist 176 that are disposed neither in the predetermined position of transfer gate 44 nor in the predetermined position of the transfer gate 50. It is noteworthy that FIG. 16 and FIG. 17 do not show all the components in the photo-sensing region 41 for clarity of illustration.

It is noteworthy that the order of the processes for fabricating the CMOS image sensor should not to be limited to the above embodiments in the present invention. The designed photodiode 58 and the various transistor structures can be formed in the meantime in the photo-sensing region 41 and in the transistor region 43 respectively. In another embodiment of the present invention, the photodiode 58 can be formed in the photo-sensing region 41 before the gate structures and the doped regions are formed in the transistor region 43. In another embodiment, the gate structures and the doped regions can be formed in the transistor region 43 before the photodiode 58 is completed in the photo-sensing region 41. On the other hand, a P-type well can be formed within the substrate 40 of the photo-sensing region 41 in the present invention. The P-type well of the photo-sensing region 41 and the P-type well 52 of the transistor region 43 can be formed simultaneously in the same ion implantation process. Otherwise, the P-type well of the photo-sensing region 41 can be formed before or after the P-type well 52 of the transistor region 43.

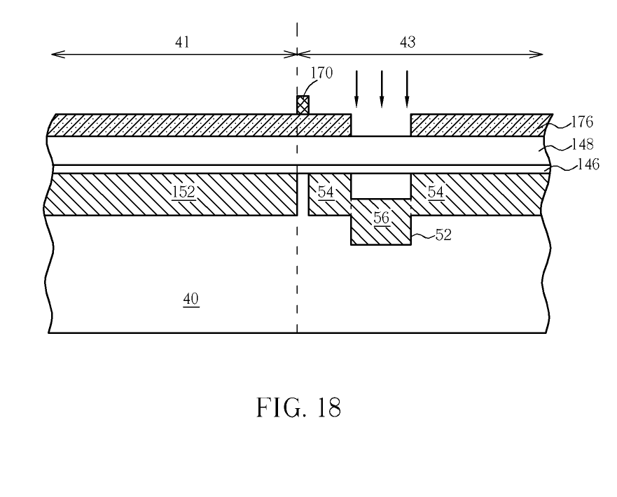

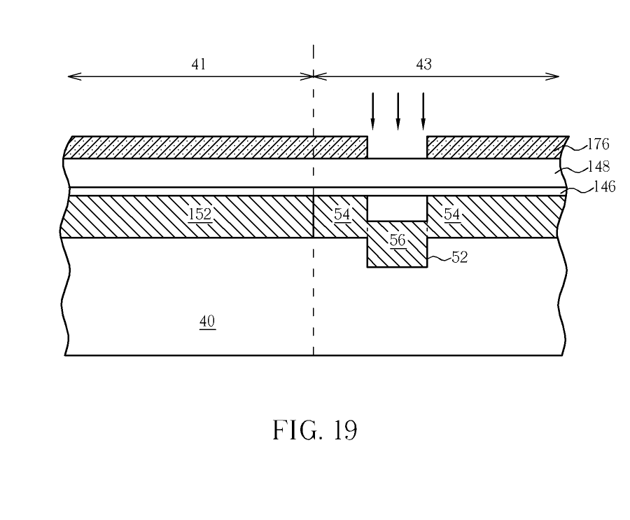

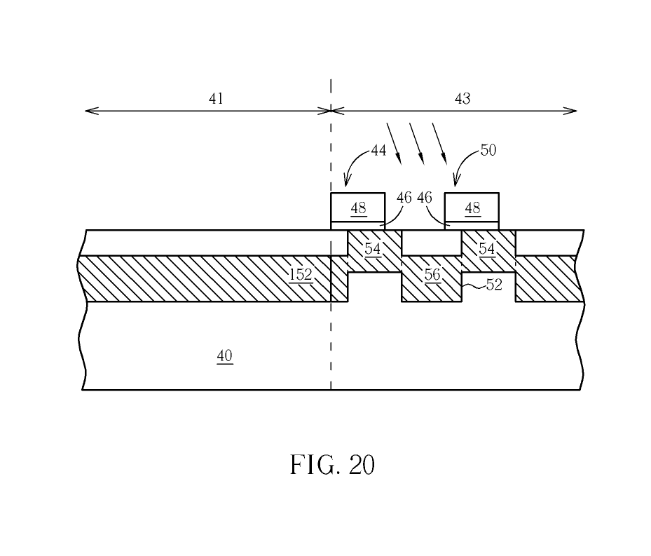

Please refer to FIG. 18 to FIG. 20, which are schematic diagrams illustrating methods for forming a CMOS image sensor in accordance with the tenth to the twelfth preferred embodiments of the present invention respectively. As shown in FIG. 18, the ion implant mask 170 can only cover parts of the patterned photoresist 176 that is disposed within the predetermined position of the transfer gate 44, and exposes the patterned photoresist 176 disposed in the photo-sensing region 41 during the ion implantation process. As shown in FIG. 19 and FIG. 20, the present invention can even have no implant mask in the transistor region 41 and in the photo-sensing region 43 during the ion implantation process. Thus, a P-type well 152 can be formed in the photo-sensing region 41 by utilizing the same ion implantation process for forming the P-type well 52 simultaneously in the tenth to the twelfth preferred embodiments of the present invention.

In sum, the implant depth and position of the P-type well can be easily and simply adjusted by the gate conductor, which is formed in advance, and the fabricating process disclosed in the present invention can prevent the defects caused by the ion implant energy in the channel region of the transistor. Furthermore, the CMOS image sensor can have a better layout in the present invention, and the dark current intensity is effectively reduced.

Those skilled in the art will readily observe that numerous modifications and alterations of the device and method may be made while retaining the teachings of the invention.

1. A method of forming a complementary metal-oxide-semiconductor (CMOS) image sensor, comprising:
providing a substrate, the substrate comprising at least a photo-sensing region and at least a transistor region;
forming at least a gate structure on a surface of the substrate within the transistor region; and
performing an ion implantation process on the substrate through the gate structure to form a first conductive type well within the substrate in the transistor region, the first conductive type well comprising at least a first well region and at least a second well region.

2. The method of claim 1, wherein the first well region is shadowed by the gate structure in the ion implantation process, and the second well region is not shadowed by the gate structure in the ion implantation process, so the first well region is closer to the surface of the substrate than the second well region.

3. The method of claim 1, wherein the ion implantation process is performed toward the substrate and tilts from the photo-sensing region toward the transistor region.

4. The method of claim 1, wherein the ion implantation process is performed toward the substrate and tilts from the transistor region toward the photo-sensing region.

5. The method of claim 1, wherein the surface of the substrate in the photo-sensing region is covered by a patterned photoresist in the ion implantation process.

6. The method of claim 1, wherein the surface of the substrate in the photo-sensing region is exposed to the ion implantation process.

7. The method of claim 1, further comprising of forming at least a second conductive type region within the substrate at a side of the gate structure opposite to the photo-sensing region after the ion implantation process.

8-20. (canceled)
